(19) United States
(12) Patent Application Publication
(10) Pub. No.: US 2013/0269989 A1
(43) Pub. Date: Oct. 17, 2013

(54) PREPREG AND PRINTED CIRCUIT BOARD COMPRISING THE SAME AND MANUFACTURING METHOD PRINTED CIRCUIT BOARD

(71) Applicant: SAMSUNG ELECTRONICS CO., LTD., Suwon (KR)

(72) Inventor: Yoon Shik KIM, Suwon (KR)

(73) Assignee: SAMSUNG ELECTRONICS CO., LTD., Suwon (KR)

(21) Appl. No.: 13/859,410

(22) Filed: Apr. 9, 2013

(30) Foreign Application Priority Data
Apr. 12, 2012 (KR) 10-2012-0037652

(51) Int. Cl. H05K 1/03; H05K 3/06

(52) U.S. Cl. CPC H05K 1/0366; H05K 1/036; H05K 3/06
USPC 174/255; 428/320.2; 442/226; 442/374; 216/13; 174/258

(57) ABSTRACT

The present invention relates to a prepreg including an insulating resin composition impregnated into a substrate including a fibrous material and a porous support, and a printed circuit board including the same as an insulating layer.

According to the present invention, it is possible to improve fire resistance, reduce weight, and reinforce mechanical characteristics by using a mixture of the fibrous material and the porous support as the substrate used for impregnation of the insulating resin composition and disposing the porous support around the fibrous material. Further, it is possible to reinforce local/overall strengths, facilitate manufacture of the product, increase resistance to bending stress, aseismatic, fireproof, and durable types, and secure improvement in a coefficient of thermal expansion by combining the porous support and a base resin and disposing the fibrous material in a main structural part which receives a force.

### CROSS-REFERENCE TO RELATED APPLICATIONS

This application claims the foreign priority benefit under 35 U.S.C. Section 119 of Korean Patent Application Serial No. 10-2012-0037652, filed Apr. 10, 2012, which is hereby incorporated by reference in its entirety into this application.

### BACKGROUND OF THE INVENTION

1. Field of the Invention

The present invention relates to a prepreg and a printed circuit board comprising the same and a manufacturing method printed circuit board.

2. Description of the Related Art

A printed circuit board (PCB) has been regarded as an essential component in almost all electronics industry-related fields including information appliances as well as electronic products. In particular, the importance of a substrate, which is connected to small electronic components, is being increased due to the recent convergence between electronic devices and miniaturization and thinning of the components.

The PCBs are classified into single-sided, double-sided, and multilayer PCBs. With the development of technologies, the ratio of the multilayer products is being increased, thus leading the market. Since the multilayer products form the basis of the newly released next-generation PCBs (embedded PCB etc.), a lamination process has been regarded as a key role in the PCB industry.

A ball grid array (BGA) product, which is a kind of PCB, is used as a package product by mounting a semiconductor thereon. However, the problems caused by the difference in the coefficient of thermal expansion (CTE) between the BGA product and the semiconductor product have a bad influence on the product quality. Further, in the process of manufacturing the BGA product, substrate warpage causes defects such as substrate damage during the process and becomes a main cause for scale abnormality and various eccentricities.

Meanwhile, in the printed circuit board, an insulating layer is formed on a substrate having a circuit pattern thereon, and the insulating layer is mainly made of a prepreg (PPG) having a structure in which a typical polymer resin composition is impregnated into glass fibers.

The glass fibers, which constitute the insulating layer, are used to give mechanical strength and scale stability of the insulating layer. Further, the polymer resin composition includes a copper foil, a polymer resin for adhesion and interlayer insulation of the glass fibers, a curing agent for curing (cross-linking) the resin to increase physical/chemical strengths, a flame retardant for giving flame retardancy, an inorganic filler for giving mechanical strength, scale stability, and flame retardancy, etc.

As in FIG. 1, a currently used prepreg 10 has a structure in which a polymer resin 11, an inorganic filler 12, and a glass fiber 13 are laminated. This structure causes warpage and scale abnormality of a substrate due to the difference in the CTE of layers, a temperature gradient in the product due to mismatch with heat radiation trend of new products such as a metal core, and reductions in uniformity and yield of the product.

The insulating layer is made of a prepreg in a semi-cured state, and in order to overcome the problems due to the difference in the CTE of the prepreg, studies on the improvement of the polymer resin, the inorganic filler, and the glass fiber have been separately conducted.

Among them, the studies on the improvement of the inorganic filler and the glass fiber are dominant, but since the inorganic filler has a negative influence on optical/mechanical drilling, the content or type of the inorganic filler is limited.

In case of the glass fiber, there are trials to reduce the CTE by the improvement of properties of glass, structure of the fiber, and a reduction in diameter of the glass fiber and secure mechanical strength and scale and elastic (shape elasticity and volume elasticity) stabilities of the insulating layer which are natural functions, but there are limitations due to processing technology.

In case of the conventional prepreg using the glass fibers as a support, the warpage or scale stability of the substrate occurs due to the changes in the CTE according to the type of the glass fibers or the direction of fiber fabrics. Therefore, the substrate has compression resistance but is weak to warpage, torsion, and tension.

Further, in case of the glass fibers, the content of the inorganic filler in the insulating resin composition is limited to minimize the difference in the CTE, and in case of the inorganic filler dispersed in the polymer resin, since the agglomeration of the inorganic filler still occurs, it is needed to overcome this problem.

Meanwhile, in order to implement a high density product, in the printed circuit board, a circuit pattern becomes finer, and a circuit method is converted from a tenting method to a semi-additive process (SAP) method.

The tenting method is a method of forming a circuit pattern on a prepreg 100 using a copper foil layer 140 and a plating layer 130 of a copper clad laminate (CCL) as in FIG. 2.

The SAP method is a method of forming a circuit pattern by forming a plating layer 130 after forming a seed layer on a prepreg 100 through electroless plating 140 without forming a circuit using copper of a CCL as in FIG. 3, and there is a problem that adhesion between the seed layer 140 and the prepreg 100 is low.

Therefore, in order to apply the SAP method, as in FIG. 4, a method of manufacturing a product using a prepreg including a primer resin or an alkaline-soluble layer has been used.

Referring to FIG. 4, a copper foil 120 is laminated on a prepreg 100 including a primer resin layer or an alkaline-soluble layer 110, drilling and desmear processes are performed, and the copper foil 120 is removed by a full-etching process. Next, a Pd layer 150 is adsorbed, a chemical copper plating 140 process is performed, a copper pattern 130 is formed using a dry film resist 160, and a final desired pattern is formed by performing stripping and etching.

However, the problems such as surface abnormality of the resin, non-plating, and low peel strength (deterioration of adhesion between resin and circuit) occur after full etching during the process. Therefore, neutralization and baking processes are added for improvement, but the addition of the neutralization and baking processes is not a fundamental solution and defects continuously occur.

Further, surface warpage and warpage due to the difference in the CTE during semiconductor packaging occur. Thus, there is a risk of circuit failure due to low peel strength and surface abnormality of the resin, and there are unsolved disadvantages such as lack of compression resistance and weakness to tension.

Therefore, the conventional method has disadvantages such as a high risk of pattern lifting, high process costs due to many unnecessary processes (full etching, baking, etc) and use of unnecessary materials, a high risk of fine circuit pattern defects due to surface abnormality of the resin, lack of compression resistance, and weakness to warpage, torsion, and tension. Thus, a printed circuit board, which can overcome these problems, is needed.

### SUMMARY OF THE INVENTION

The present invention has been invented in order to overcome the conventional problems of an insulating layer of a printed circuit board, which is used in the form of a prepreg obtained by impregnating an insulating resin composition into a support such as glass fibers, due to the difference in the coefficient of thermal expansion between the support and the insulating resin composition and it is, therefore, an object of the present invention to provide a prepreg that has excellent properties without occurrence of warpage or torsion of a substrate as well as improves the problems due to the difference in the coefficient of thermal expansion by using a novel support.

Further, it is another object of the present invention to provide a printed circuit board including an insulating layer made of a prepreg and a manufacturing method of the same.

In accordance with one aspect of the present invention to achieve the object, there is provided a prepreg prepared by impregnating an insulating resin composition into a substrate including a fibrous material and a porous support.

The fibrous material may be at least one selected from the group consisting of glass fibers, woven glass fibers, woven alumina glass fibers, glass fiber non-woven fabrics, silica glass fibers, woven carbon fibers, carbon fibers, cellulose non-woven fabrics, polymer fabrics, alumina fibers, silicon carbide fibers, asbestos, rock wool, mineral wool, gypsum whisker, and woven fabrics or non-woven fabrics thereof, liquid crystal polyester, polyester fibers, fluoride fibers, polybenzoxazole fibers, glass fibers with polyamide fibers, glass fibers with carbon fibers, glass fibers with polyimide fibers, glass fibers with aromatic polyester, glass paper, mica paper, alumina paper, kraft paper, cotton paper, and paper-glass combined paper.

The fibrous material may be included in the form of a fabric or a sheet.

It is preferred that the porous support has a specific surface area of 200 to 2000 m²/g.

It is preferred that the porous support has a pore size of less than 80 μm.

The porous support may be at least one selected from at least one porous inorganic material selected from the group consisting of aerogel, silica, fused silica, glass, alumina, platinum, nickel, titania, zirconia, ruthenium, cobalt, and combinations thereof; and at least one porous polymer selected from the group consisting of urea resins, phenol resins, polystyrene resins, and combinations thereof.

The insulating resin composition in accordance with the present invention may include a base resin and a filler.

The base resin may be at least one epoxy resin selected from at least one phenol glycidylether epoxy resin selected from the group consisting of phenol novolac epoxy resins, cresol novolac epoxy resins, naphthol-modified novolac epoxy resins, bisphenol A epoxy resins, bisphenol F epoxy resins, biphenyl epoxy resins, and triphenyl epoxy resins; dicyclopentadiene epoxy resins having a dicyclopentadiene skeleton; naphthalene epoxy resins having a naphthalene skeleton; dihydroxybenzopyran epoxy resins; glycidylamine epoxy resins; triphenolmethane epoxy resins; tetraphenylethane epoxy resins; and mixtures thereof.

The porous support may include a filler.

The base resin may be included in an amount of 10 to 80 wt % of the insulating resin composition.

Further, in accordance with another aspect of the present invention to achieve the object, there is provided a printed circuit board including an insulating layer made of a prepreg.

In accordance with an embodiment of the present invention, a circuit pattern of the printed circuit board may be formed by at least one method selected from the group consisting of a semi-additive process (SAP) method, a modified semi-additive process (MSAP) method, and an advanced modified semi-additive process (AMSAP) method.

The circuit pattern of the printed circuit board may be formed on a porous support in the prepreg, and the circuit pattern may be formed on a surface of the porous support and in a pore of the porous support.

In accordance with an embodiment of the present invention, the insulating layer may be an insulation film.

Further, in accordance with still another aspect of the present invention to achieve the object, there is provided a multilayer printed circuit board including: an insulating layer made of a prepreg; and a copper foil and a polymer film formed on at least one of an upper surface and a lower surface of the insulating layer.

In accordance with an embodiment of the present invention, the insulating layer may be included as a plurality of layers, and the types or shapes of fibrous materials included in the plurality of insulating layers may be different from each other.

In accordance with an embodiment of the present invention, the plurality of insulating layers may include prepregs having different asymmetric structures in an upper surface and a lower surface thereof.

Meanwhile, it is another object of the present invention to provide a method for manufacturing a printed circuit board, comprising: forming an insulating layer formed of a prepreg made of a porous support and a fibrous material; exposing a portion of structure of the porous support included into the insulating layer; performing a chemical copper plating on the porous support; and forming a circuit pattern on the porous support.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 shows a structure of a prepreg which is an insulating layer;

FIG. 2 shows a method of forming a circuit pattern using a tenting method;

FIG. 3 shows a method of forming a circuit pattern using a SAP method;

FIG. 4 shows a method of forming a circuit pattern by a SAP method using a primer resin;

FIG. 5 shows a structure of a prepreg in accordance with an embodiment of the present invention;

FIG. 6 shows a printed circuit board in accordance with an embodiment of the present invention;

FIG. 7 shows a process of manufacturing a printed circuit board in accordance with an embodiment of the present invention;

FIG. 8 illustrates a printed circuit board using a porous support as a support of a circuit pattern; and

FIGS. 9, 10A and B, and 11 show examples of a structure of a multilayer printed circuit board including a prepreg insulating layer in accordance with an embodiment of the present invention.

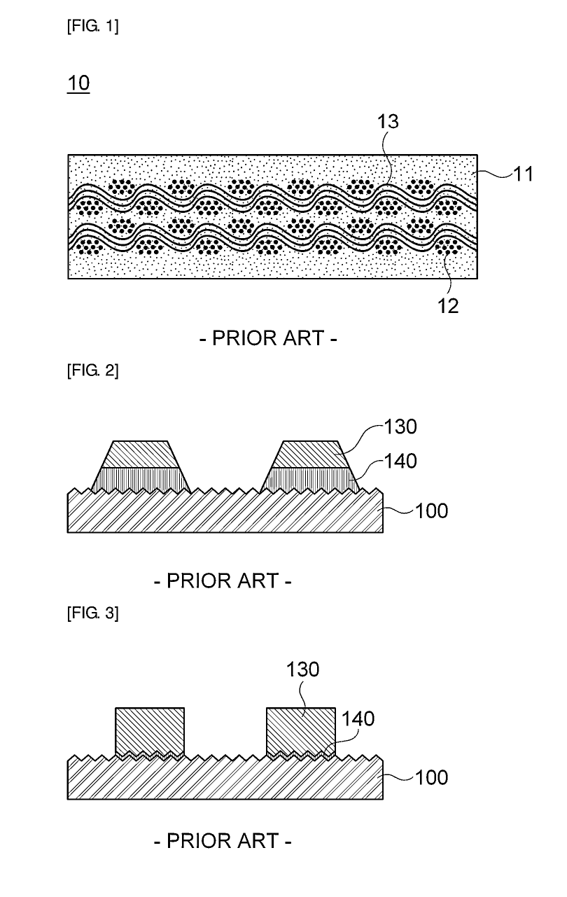

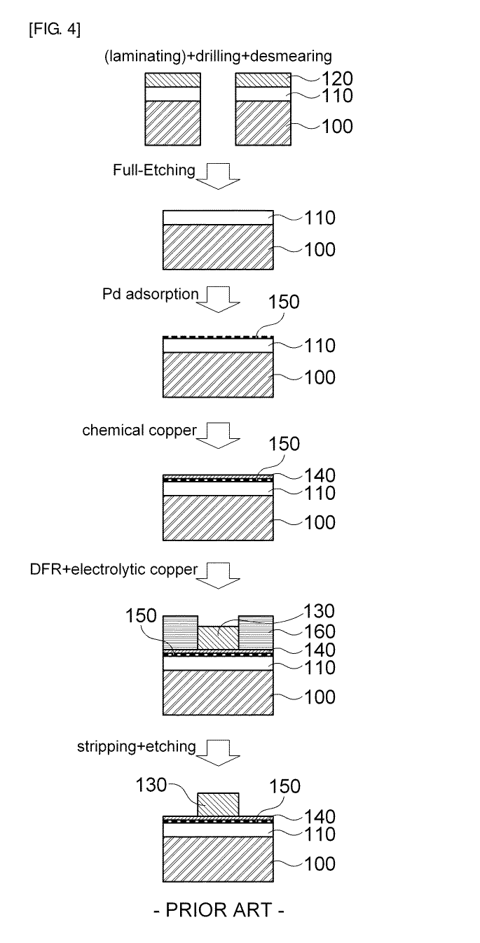

### DETAILED DESCRIPTION OF THE PREFERABLE EMBODIMENTS

Hereinafter, the present invention will be described in detail with reference to the accompanying drawings.

Terms used herein are provided to explain specific embodiments, not limiting the present invention. Throughout this specification, the singular form includes the plural form unless the context clearly indicates otherwise. Further, terms “comprises” and/or “comprising” used herein specify the existence of described shapes, numbers, steps, operations, members, elements, and/or groups thereof, but do not preclude the existence or addition of one or more other shapes, numbers, operations, members, elements, and/or groups thereof.

The present invention relates to a prepreg obtained by impregnating an insulating resin composition into a substrate including a fibrous material and a porous support, and a printed circuit board including the prepreg as an insulating layer.

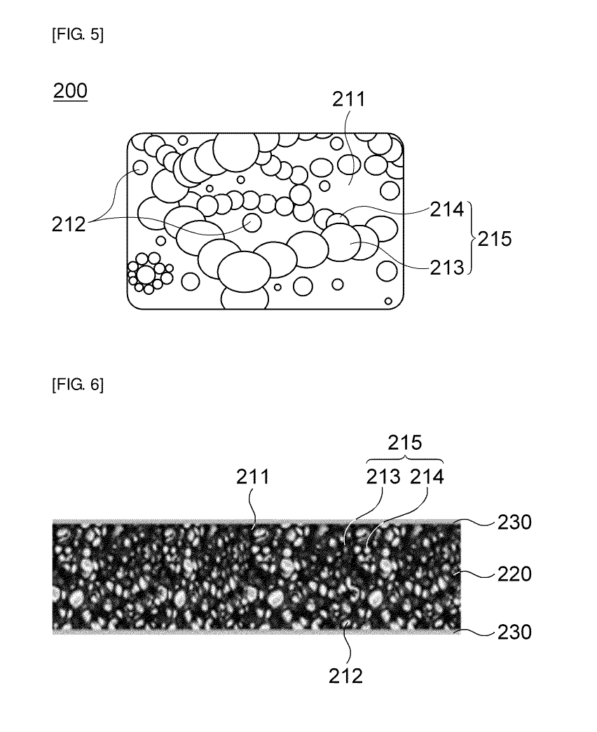

A prepreg 200 in accordance with the present invention is as shown in FIG. 5.

The prepreg 200 of the present invention has a structure in which a substrate 215 including a porous support 213 and a fibrous material 214 is impregnated with an insulating resin composition including a base resin 211 and a filler 212.

In the past, when manufacturing a product using a prepreg which includes only glass fibers, internal local mechanical properties are secured, but a coefficient of thermal expansion varies according to the direction of fabric (fibers), thus causing defects.

Therefore, in the present invention, the fibrous material is included in the porous support to be used as the substrate of the insulating resin composition by overcoming disadvantages of the porous support which has few risks of CTE-related defects due to heat resistance, wide surface area, and no directivity of CTE but has weak mechanical strength.

The fibrous material in accordance with the present invention may be at least one selected from the group consisting of glass fibers, woven glass fibers, woven alumina glass fibers, glass fiber non-woven fabrics, silica glass fibers, woven carbon fibers, carbon fibers, cellulose non-woven fabrics, polymer fabrics, alumina fibers, silicon carbide fibers, asbestos, rock wool, mineral wool, gypsum whisker, and woven fabrics or non-woven fabrics thereof, liquid crystal polyester, polyester fibers, fluoride fibers, polybenzoxazole fibers, glass fibers with polyamide fibers, glass fibers with carbon fibers, glass fibers with polyimide fibers, glass fibers with aromatic polyester, glass paper, mica paper, alumina paper, kraft paper, cotton paper, and paper-glass combined paper.

The fibrous material may be included in the form of a fabric or a sheet.

As in FIG. 5, since the porous support 213 in accordance with the present invention has a porous structure including numerous pores, it has a wide surface area. For example, it is preferred that the porous support 213 in accordance with the present invention has a specific surface area of 200 to 2000 m²/g.

When the specific surface area of the porous support 213 in accordance with the present invention is less than 200 m²/g, heat resistance is insufficient. Further, when the specific surface area of the porous support 213 is too large and thus exceeds 2000 m²/g, it is not preferred since mechanical properties are deteriorated.

Further, the porous support 213 in accordance with the present invention is characterized by excellent thermal stability and no directivity of the coefficient of thermal expansion. Thus, the porous support 213 in accordance with the present invention can be preferably used by minimizing problems such as warpage and scale abnormality of a substrate due to changes in the coefficient of thermal expansion of glass fibers used as the conventional support according to the direction of the fibers. Further, in case of the glass fibers, the content of the filler in the insulating resin composition is limited to minimize the difference in the coefficient of thermal expansion, and agglomeration of the filler occurs.

However, when using the porous support in accordance with the present invention, as in FIG. 5, the filler 212 can introduced between the porous supports 213 so that it is possible to minimize the agglomeration of the filler. Further, it is preferred since the properties of the porous support 213 can be reinforced by including the fibrous material 214.

That is, in the present invention, the filler may be included in the insulating resin composition or previously included in the insulating resin composition and the porous support. When the filler is included in the porous support, the filler may be previously distributed between the pores of the porous support by spraying etc. In this case, it is possible to overcome the agglomeration of the filler by uniformly distributing the filler.

The size of the pores included in the porous support 213 in accordance with the present invention is less than 80 μm, preferably 0.01 to 30.00 μm in terms of introduction and distribution of the filler according to the impregnation.

The porous support of the present invention having these characteristics may be at least one selected from at least one porous inorganic material selected from the group consisting of aerogel, silica, fused silica, glass, alumina, platinum, nickel, titania, zirconia, ruthenium, cobalt, and combinations thereof: and at least one porous polymer selected from the group consisting of urea resins, phenol resins, polystyrene resins, and combinations thereof. Among them, aerogel may be most preferably used.

Since the substrate in accordance with the present invention has excellent properties and can simply replace the conventional support, it is easy to prepare the prepreg.

Meanwhile, the insulating resin composition in accordance with the present invention may include the base resin and the filler. The insulating resin composition is used for interlayer insulation, and the base resin may be a polymer resin having excellent insulation characteristics, which is used in the conventional insulating layer.

In the present invention, particularly, the base resin may be various types of epoxy resins. For example, the base resin may be at least one selected from at least one phenol glycidylether epoxy resin selected from the group consisting of phenol novolac epoxy resins, cresol novolac epoxy resins, naphthol-modified novolac epoxy resins, bisphenol A epoxy resins, bisphenol F epoxy resins, biphenyl epoxy resins, and triphenyl epoxy resins; dicyclopentadiene epoxy resins having a dicyclopentadiene skeleton; naphthalene epoxy resins having a naphthalene skeleton; dihydroxybenzopyran epoxy resins; glycidylamine epoxy resins; triphenolmethane epoxy resins; tetraphenylethane epoxy resins; and mixtures thereof.

More specifically, the epoxy resin may be N,N,N′,N-tetraglycidyl-4,4′-methylenebisbenzenamine, polyglycidyl ether of o-cresol-formaldehyde novolac, or mixtures thereof.

It is preferred that the epoxy resin is included in an amount of 10 to 80 wt % of the entire circuit board composition. When the epoxy resin is included within the above range, it is possible to improve adhesion between the insulating composition and a metal such as copper, chemical resistance, thermal characteristics, and scale stability.

Further, the filler in accordance with the present invention may include both of an organic filler and an inorganic filler, and although not particularly limited, may include at least one inorganic filler selected from natural silica, fused silica, amorphous silica, hollow silica, aluminum hydroxide, boehmite, magnesium hydroxide, molybdenum oxide, zinc molybdate, zinc borate, zinc stannate, aluminum borate, potassium titanate, magnesium sulfate, silicon carbide, zinc oxide, silicon nitride, silicon oxide, aluminum titanate, barium titanate, barium strontium titanate, aluminum oxide, alumina, clay, kaoline, talc, calcined clay, calcined kaoline, calcined talc, mica, short glass fibers, and mixtures thereof.

For example, although not limited thereto, the organic filler may be epoxy resin powder, melamine resin powder, urea resin powder, benzoguanamine resin powder, styrene resin, etc.

Further, unless deteriorating the properties of the prepreg of the present invention, the insulating resin composition of the present invention may further include an additive such as a filler, a softener, a plasticizer, an antioxidant, a flame retardant, an auxiliary flame retardant, a lubricant, an antistatic agent, a coloring agent, a heat stabilizer, a light stabilizer, a UV absorber, a coupling agent, or an anti-settling agent, and the type and content thereof aren't particularly limited.

The insulating resin composition for a printed circuit board in accordance with an embodiment of the present invention may be prepared by blending the above components by various methods such as room temperature mixing and melt mixing.

The prepreg in accordance with the present invention may be prepared by mixing the insulating resin composition and the substrate. More specifically, the prepreg may be prepared by applying or impregnating the insulating resin composition into the substrate, curing the insulating resin composition, and removing a solvent. For example, although not limited thereto, the impregnation method may be dip coating, roll coating, etc.

The insulating resin composition may be impregnated in an amount of about 100 to 30,000 parts by weight based on 100 parts by weight of the substrate. When the content of the impregnated insulating resin composition is less than 100 parts by weight, the insulating resin composition isn't impregnated, and when exceeding 30,000 parts by weight, it is not preferred that thermal effects of the substrate are deteriorated.

When the insulating resin material is impregnated within the above range, the mechanical strength and scale stability of the prepreg can be improved. Further, the adhesive strength of the prepreg is improved and thus the adhesion with other prepregs can be improved.

Further, the porous support included in the substrate of the present invention may include the filler. For example, after the filler is previously dispersed between the pores of the porous support, the insulating resin composition is impregnated into the filler-dispersed porous support.

FIG. 6 shows a printed circuit board in accordance with an embodiment of the present invention. The printed circuit board may include an insulating layer 220 made of a prepreg having a structure in which an insulating resin composition including a base resin 211 and a filler 212 is impregnated into a substrate 215 including a porous support 213 and a fibrous material 214 shown in FIG. 5; and a circuit pattern 230 formed on one or both surfaces of the insulating layer. In accordance with an embodiment of the present invention, the insulating layer may be an insulation film.

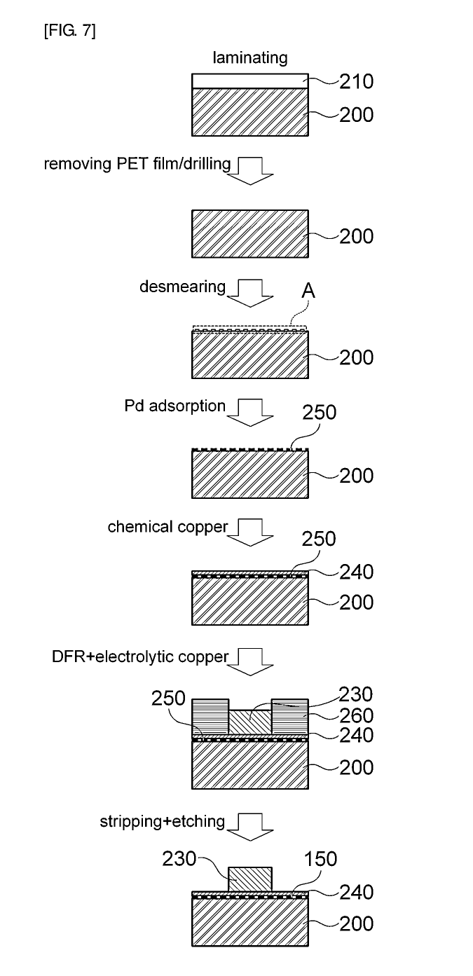

FIG. 7 shows a process of manufacturing a printed circuit board in accordance with an embodiment of the present invention. After a PET film 210 is laminated on a prepreg 200 prepared from a porous support and a fibrous material, the PET film 210 is removed and then drilling is performed. The PET film used here is generally a fat-soluble product, but the type thereof is not limited since a water-soluble film, which can be removed by a cleaning process, can be also used.

Next, a desmear process is performed. A portion A of the structure of the porous support 213 is exposed to the surface by the desmear process. In the past, a separate surface roughness should be formed by the desmear process, but in the present invention, since the portion of the structure of the porous support is exposed to the surface during the desmear process, a predetermined roughness is formed on the surface without a separate surface treatment process. The exposure of the structure by the desmear process is to utilize a process of removing a smear (a phenomenon due to melting and sticking of epoxy on an inner wall of a hole when the hole is processed) generated during the previously performed drilling.

Further, when not performing the desmear process used in the past, the portion of the structure of the porous support may be exposed regardless of the desmear process by treating water-soluble surface coating when preparing the prepreg 200 of the porous support. The surface roughness is determined by the size of pores of the porous support, and the surface shape is adjusted by the surface coating.

Therefore, a circuit pattern 230 of the printed circuit board in accordance with the present invention is formed on the porous support 213. Since the porous support 213 in accordance with the present invention has numerous pores inside thereof, the circuit pattern 230 can be formed both on the surface of the porous support 213 and in the pores inside the porous support 213. Therefore, the porous support 213 improves interfacial adhesion by forming a physically cross-linked structure between the circuit pattern 230 and an insulating layer.

Further, in order to form a roughness between a circuit and a resin in the conventional product, a copper foil is laminated to transfer a roughness thereof to a surface of a prepreg (a non-plating defect may occur during formation of a plating layer by a surfactant of a matte surface when using a copper foil) or a primer resin or an alkaline-soluble layer is used. However, in the present invention, it is possible to secure adhesion and overcome defects such as surface abnormality of a resin not by utilizing a roughness of the resin layer but by using the roughness of the porous support.

Next, Pd 250 is adsorbed, a chemical copper plating 240 process is performed, and a plating layer is formed using a dry film resist 260 to form the circuit pattern 230, and a final desired pattern is formed by performing stripping and etching.

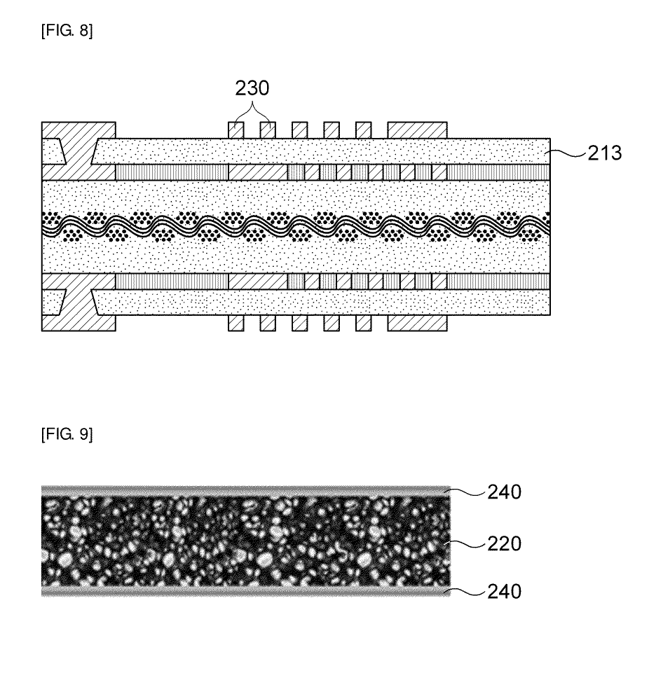

As in FIG. 8, the printed circuit board in accordance with the present invention can secure stability of mechanical properties compared to a polymer resin by using the porous support 213 having a wide surface area as a support of the circuit pattern 230.

Further, since the porous support in accordance with the present invention has no directivity of the coefficient of thermal expansion, there is no warpage or scale abnormality of the product. Thus, it is possible to relatively secure technical superiority during packaging. In case of materials having a low coefficient of thermal expansion of other companies, the content of an inorganic filler is relatively high and processibility is deteriorated due to occurrence of agglomeration, but since the present invention can implement a low coefficient of thermal expansion even by the relatively low content of the inorganic filler, it is possible to improve processing quality.

Further, it is possible to improve adhesion by adding mechanical and structural methods of the porous support to curing and coupling through heat and pressure.

Further, when impregnating the prepreg including the porous support in the resin, as the organic filler is distributed in the porous aerogel, it is efficient in improving the CTE compared to the product using only glass fibers as a support. Although the prepreg isn't impregnated in the resin, it is possible to be applied to a heat radiation system since only a portion in contact during packaging is surface-treated to fill the pores and the remaining portion is maintained in a pore state.

The surface roughness can be adjusted by structural change or adjustment of the porous support, and the capability of implementing a fine pattern is high by maintaining the surface roughness low. Thus, it is possible to implement an additional fine circuit by previously preventing additional defects (residual copper etc.) during formation of the circuit, and it is possible to minimize leak defects by removing the cause of the residual copper etc.

Further, it is possible to improve processing efficiency by not using a copper foil in forming the circuit pattern and thus directly processing the circuit pattern on the surface of the prepreg of the present invention having a relatively high CO₂ absorption rate.

FIGS. 9, 10A, 10B, and 11 show various printed circuit boards in accordance with embodiments of the present invention.

Referring to FIG. 9, the printed circuit board may be a copper clad laminate including an insulating layer 220 and copper foils 240 formed on both surfaces of the insulating layer. Further, although not shown, the copper foil may be formed on only one surface of the insulating layer.

As described above, it is preferred that the insulating layer 220 is a prepreg prepared by impregnating an insulating resin composition in accordance with an embodiment of the present invention into a substrate including a porous support and a fibrous material.

The copper foil 240 is formed on the insulating layer 220 and heat-treated to form the copper clad laminate. A circuit pattern may be formed by patterning the copper foil 240 of the copper clad laminate.

Further, a polymer film may be included instead of the copper foil 240.

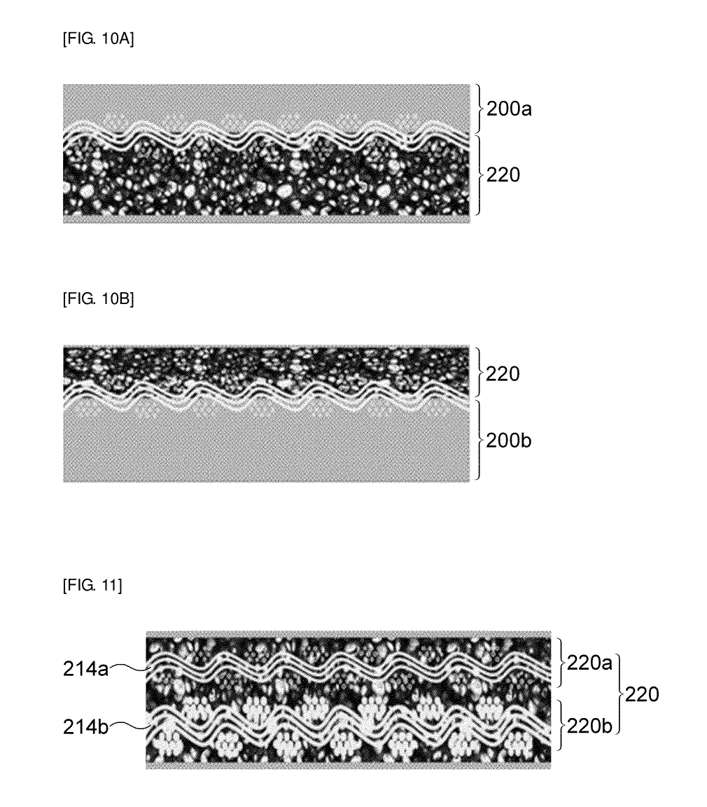

In accordance with an embodiment of the present invention, as in FIGS. 10A and 10B, prepregs 200a and 200b included in an upper surface and a lower surface of an insulating layer 220 may have different asymmetric structures.

In accordance with an embodiment of the present invention, as in FIG. 11, an insulating layer 220 may consist of a plurality of layers 220a and 220b, and the types or shapes of fibrous materials 214a and 214b included in the plurality of insulating layers may be different from each other.

Since the insulating layer of the present invention, which is made of the prepreg, has a conductor circuit pattern, it can be applied to all of various printed circuit boards requiring interlayer insulation.

Further, in accordance with an embodiment of the present invention, the circuit pattern of the printed circuit board may be formed by at least one method selected from the group consisting of a semi-additive process (SAP) method, a modified semi-additive process (MSAP) method, and an advanced modified semi-additive process (AMSAP) method.

The printed circuit boards in accordance with the present invention are classified into motherboards for mounting a component and IC substrates for mounting a semiconductor and may be classified into rigid substrates such as epoxy resins, phenol resins, and bismaleimide-triazine (BT); flexible substrates using polyimide; and special substrates such as metal cores, ceramic cores, rigid-flexible substrates, embedded substrates, and optical substrates according to the material. Further, the printed circuit boards may be classified into single-layered, double-layered, and multilayer substrates according to the number of layers and classified into ball grid array (BGA), pin grid array (PGA), and land grid array (LGA) according to the shape. The present invention can be used for various printed circuit boards listed above.

According to the present invention, it is possible to improve fire resistance, reduce weight, and reinforce mechanical characteristics by using a mixture of a fibrous material and a porous support as a substrate used for impregnation of an insulating resin composition and disposing the porous support around the fibrous material. Further, it is possible to reinforce local/overall strengths, facilitate manufacture of the product, increase resistance to bending stress, aseismatic, fireproof, and durable types, and secure improvement in a coefficient of thermal expansion compared to the conventional product by combining the porous support, which is strong against tension but weak against compressive strength, and a base resin, which is weak against tension but strong against compressive strength, and disposing the fibrous material in a main structural part which receives a force.

Further, even though damage occurs from the outside, the damage isn't expanded and occurs locally due to the adjacent porous supports, and it is possible to improve properties for compressive load and reduce damages to a printed circuit board due to a porous structure.

What is claimed is:

1. A prepreg prepared by impregnating an insulating resin composition into a substrate including a fibrous material and a porous support.

2. The prepreg according to claim 1, wherein the fibrous material is at least one selected from the group consisting of glass fibers, woven glass fibers, woven alumina glass fibers, glass fiber non-woven fabrics, silica glass fibers, woven carbon fibers, carbon fibers, cellulose non-woven fabrics, polymer fabrics, alumina fibers, silicon carbide fibers, asbestos, rock wool, mineral wool, gypsum whisker, and woven fabrics or non-woven fabrics thereof, liquid crystal polyester, polyester fibers, fluoride fibers, polybenzoxazole fibers, glass fibers with polyamide fibers, glass fibers with carbon fibers, glass fibers with polyimide fibers, glass fibers with aromatic polyester, glass paper, mica paper, alumina paper, kraft paper, cotton paper, and paper-glass combined paper.

3. The prepreg according to claim 1, wherein the fibrous material is included in the form of a fabric or a sheet.

4. The prepreg according to claim 1, wherein the porous support has a specific surface area of 200 to 2000 m²/g.

5. The prepreg according to claim 1, wherein the porous support has a pore size of less than 80 μm.

6. The prepreg according to claim 1, wherein the porous support is at least one selected from at least one porous inorganic material selected from the group consisting of aerogel, silica, fused silica, glass, alumina, platinum, nickel, titania, zirconia, ruthenium, cobalt, and combinations thereof; and at least one porous polymer selected from the group consisting of urea resins, phenol resins, polystyrene resins, and combinations thereof.

7. The prepreg according to claim 1, wherein the insulating resin composition includes a base resin and a filler.

8. The prepreg according to claim 7, wherein the base resin includes at least one epoxy resin selected from at least one phenol glycidylether epoxy resin selected from the group consisting of phenol novolac epoxy resins, cresol novolac epoxy resins, naphthol-modified novolac epoxy resins, bisphenol A epoxy resins, bisphenol F epoxy resins, biphenyl epoxy resins, and triphenyl epoxy resins; dicyclopentadiene epoxy resins having a dicyclopentadiene skeleton; naphthalene epoxy resins having a naphthalene skeleton; dihydroxybenzopyran epoxy resins; glycidylamine epoxy resins; triphenolmethane epoxy resins; tetraphenylethane epoxy resins; and mixtures thereof.

9. The prepreg according to claim 1, wherein the porous support includes a filler.

10. The prepreg according to claim 7, wherein the base resin is included in an amount of 10 to 80 wt % of the insulating resin composition.

11. A printed circuit board comprising an insulating layer made of a prepreg according to claim 1.

12. The printed circuit board according to claim 11, wherein the printed circuit board comprises a circuit pattern formed by at least one method selected from the group consisting of a semi-additive process (SAP) method, a modified semi-additive process (MSAP) method, and an advanced modified semi-additive process (AMSAP) method.

13. The printed circuit board according to claim 12, wherein the circuit pattern of the printed circuit board is formed on a porous support in the prepreg, and the circuit pattern is formed on a surface of the porous support and in a pore of the porous support.

14. The printed circuit board according to claim 11, wherein the insulating layer is an insulation film.

15. A multilayer printed circuit board comprising:
an insulating layer made of a prepreg according to claim 1; and
a copper foil and a polymer film formed on at least one of an upper surface and a lower surface of the insulating layer.

16. The multilayer printed circuit board according to claim 15, wherein the insulating layer is included as a plurality of layers, and the types or shapes of fibrous materials included in the plurality of insulating layers are different from each other.

17. The multilayer printed circuit board according to claim 16, wherein the plurality of insulating layers include prepregs having different asymmetric structures in an upper surface and a lower surface thereof.

18. A method for manufacturing a printed circuit board, comprising:
forming an insulating layer formed of a prepreg made of a porous support and a fibrous material;
exposing a portion of structure of the porous support included into the insulating layer;
performing a chemical copper plating on the porous support; and
forming a circuit pattern on the porous support.

19. The method for manufacturing the printed circuit board according to claim 18, wherein exposing a portion of structure of the porous support included into the insulating layer is implemented by performing a desmear process to the porous support or coating a surface of the prepreg made of the porous support and the fibrous material water-solubly.

20. The method for manufacturing the printed circuit board according to claim 18, wherein the circuit pattern is formed in a surface of the porous support and in a pore of the porous support.

21. The method for manufacturing the printed circuit board according to claim 18, further comprising:
forming a copper and a polymer film on at least one among a top surface of a bottom surface of the insulating layer additionally.

22. The method for manufacturing the printed circuit board according to claim 18, wherein forming the insulating layer is performed in such a way that the insulating layer includes a plurality of layers; and
the plurality of insulating layers include prepregs having different asymmetric structures.
